(19) United States
(12) Patent Application Publication
(10) Pub. No.: US 2014/0374150 A1
(43) Pub. Date: Dec. 25, 2014

(54) PACKAGE SUBSTRATE AND METHOD FOR MANUFACTURING PACKAGE SUBSTRATE

(71) Applicant: IBIDEN CO., LTD., Ogaki-shi (JP)

(72) Inventors: Yasushi INAGAKI, Ogaki-shi (JP); Yasuhiro Takahashi, Ogaki-shi (JP); Satoshi Kurokawa, Ogaki-shi (JP)

(73) Assignee: IBIDEN CO., LTD., Ogaki-shi (JP)

(21) Appl. No.: 14/310,354

(22) Filed: Jun. 20, 2014

(30) Foreign Application Priority Data
Jun. 20, 2013 (JP) 2013-129860

(51) Int. Cl. H05K 1/11; H05K 3/40

(52) U.S. Cl. CPC H05K 1/113; H05K 3/4007
USPC 174/258; 427/97.1

(57) ABSTRACT

A package substrate includes an outermost interlayer resin insulation layer, an outermost conductive layer formed on a first surface of the outermost interlayer resin insulation layer and including first pads positioned to mount a first electronic component and second pads positioned to mount a second electronic component, a first conductive layer including first conductive circuits and formed on a second surface of the outermost interlayer resin insulation layer on the opposite side with respect to the first surface, first via conductors penetrating through the outermost interlayer resin insulation layer such that the first via conductors are connecting the first conductive layer and the first pads, and second via conductors penetrating through the outermost interlayer resin insulation layer such that the second via conductors are connecting the first conductive layer and the second pads. The first conductive circuits in the first conductive layer are connecting the first and second pads, respectively.

### CROSS-REFERENCE TO RELATED APPLICATIONS

The present application is based upon and claims the benefit of priority to Japanese Patent Application No. 2013-129860, filed Jun. 20, 2013, the entire contents of which are incorporated herein by reference.

### BACKGROUND OF THE INVENTION

1. Field of the Invention

The present invention relates to a package substrate for mounting multiple electronic components and to a method for manufacturing such a package substrate.

2. Description of Background Art

JP H06-53349 A describes a multichip module substrate. Referring to FIG. 1 of JP H06-53349 A, two LSIs are mounted on one substrate. The two LSIs are connected to each other by multiple wiring layers. In FIG. 1 of JP H06-53349 A, multiple wiring layers are patterned in different insulation layers. The entire contents of this publication are incorporated herein by reference.

### SUMMARY OF THE INVENTION

According to one aspect of the present invention, a package substrate includes an outermost interlayer resin insulation layer, an outermost conductive layer formed on a first surface of the outermost interlayer resin insulation layer and including first pads positioned to mount a first electronic component and second pads positioned to mount a second electronic component, a first conductive layer including first conductive circuits and formed on a second surface of the outermost interlayer resin insulation layer on the opposite side with respect to the first surface, first via conductors penetrating through the outermost interlayer resin insulation layer such that the first via conductors are connecting the first conductive layer and the first pads, and second via conductors penetrating through the outermost interlayer resin insulation layer such that the second via conductors are connecting the first conductive layer and the second pads. The first conductive circuits in the first conductive layer are connecting the first pads and the second pads, respectively.

According to another aspect of the present invention, a method for manufacturing a package substrate includes forming an outermost interlayer resin insulation layer on a first conductive layer including first conductive circuits, forming on the outermost interlayer resin insulation layer an outermost conductive layer including first pads positioned to mount a first electronic component and second pads positioned to mount a second electronic component, forming first via conductors penetrating through the outermost interlayer resin insulation layer such that the first via conductors connect the first conductive layer and the first pads, and forming second via conductors penetrating through the outermost interlayer resin insulation layer such that the second via conductors connect the first conductive layer and the second pads. The first conductive circuits in the first conductive layer are connecting the first pads and the second pads, respectively.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a package substrate according to a first embodiment of the present invention;

FIG. 2 is a cross-sectional view showing an application example of the package substrate of the first embodiment;

FIG. 3(A)-3(C) are views of steps in a method for manufacturing a package substrate according to the first embodiment;

FIG. 4(A)-4(D) are views of steps in the method for manufacturing a package substrate according to the first embodiment;

FIG. 5(A)-5(C) are views of steps in the method for manufacturing a package substrate according to the first embodiment;

FIG. 6(A)-6(B) are views of steps in the method for manufacturing a package substrate according to the first embodiment;

FIG. 7(A)-7(C) are views of steps in the method for manufacturing a package substrate according to the first embodiment;

FIG. 8(A)-8(C) are views of steps in the method for manufacturing a package substrate according to the first embodiment;

FIG. 9(A)-9(C) are views of steps in the method for manufacturing a package substrate according to the first embodiment;

FIG. 10(A) is a plan view showing pad groups and FIG. 10(B) is a plan view of an application example;

FIG. 11 is a plan view of a first conductive layer;

FIG. 12 is a cross-sectional view of a package substrate according to a third embodiment;

FIG. 13(A)-13(C) are cross-sectional views of a package substrate according to a fourth embodiment;

FIG. 14 is a cross-sectional view of a skip-via conductor;

FIG. 15 is a cross-sectional view of a package substrate according to a second embodiment; and

FIG. 16(A)-16(B) are cross-sectional views of an outermost conductive layer and an outermost interlayer resin insulation layer.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

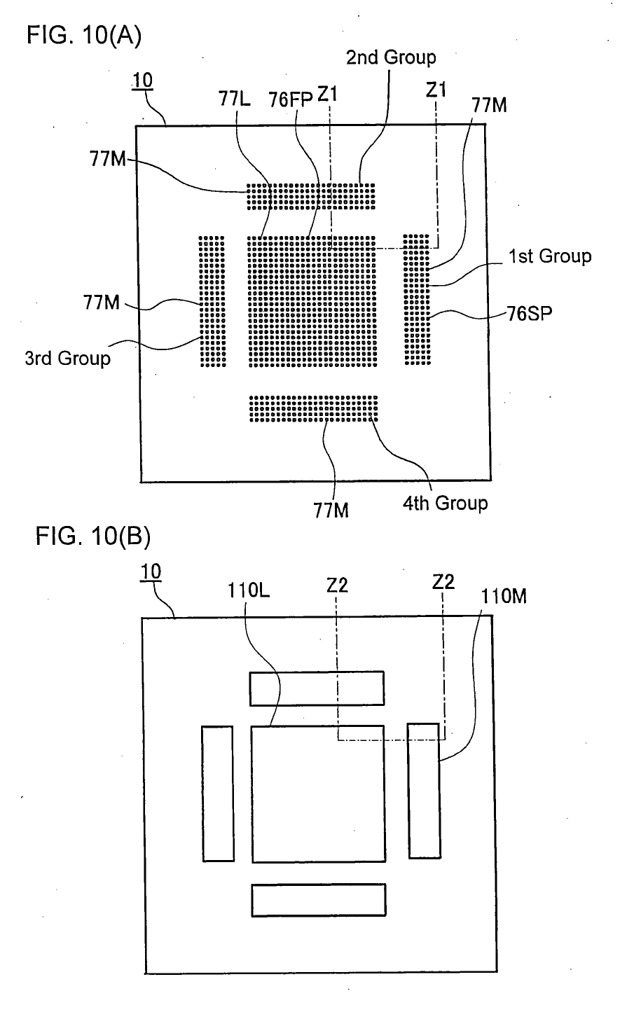

FIG. 10(A) shows a mounting surface of a package substrate according to a first embodiment of the present invention. FIG. 10(B) is a plan view illustrating an application example of the embodiment, where electronic components are mounted on the package substrate of the embodiment.

As shown in FIG. 10(A), in the central portion of the mounting surface of the package substrate, mounting region (77L) is formed for mounting a first electronic component such as a logic IC. In mounting region (77L), first pads (76FP) for mounting a first electronic component are formed in a grid. A first pad group is composed of multiple first pads (76FP). Solder bumps (76FL) for mounting a first electronic component are formed on the first pads. Mounting region (77M) for mounting a second electronic component such as a memory is formed outside mounting region (77L). In FIG. 10(A), four mounting regions (77M) are formed around mounting region (77L). In each mounting region (77M), second pads (76SP) for mounting a second electronic component are formed in a grid. A second pad group is composed of multiple second pads. Solder bumps (76FM) for mounting a second electronic component are formed on second pads. In FIG. 10(B), logic IC (110L) is mounted on solder bumps (76FL) in mounting region (77L), and memory (110M) is mounted on solder bumps (76FM) in mounting region (77M).

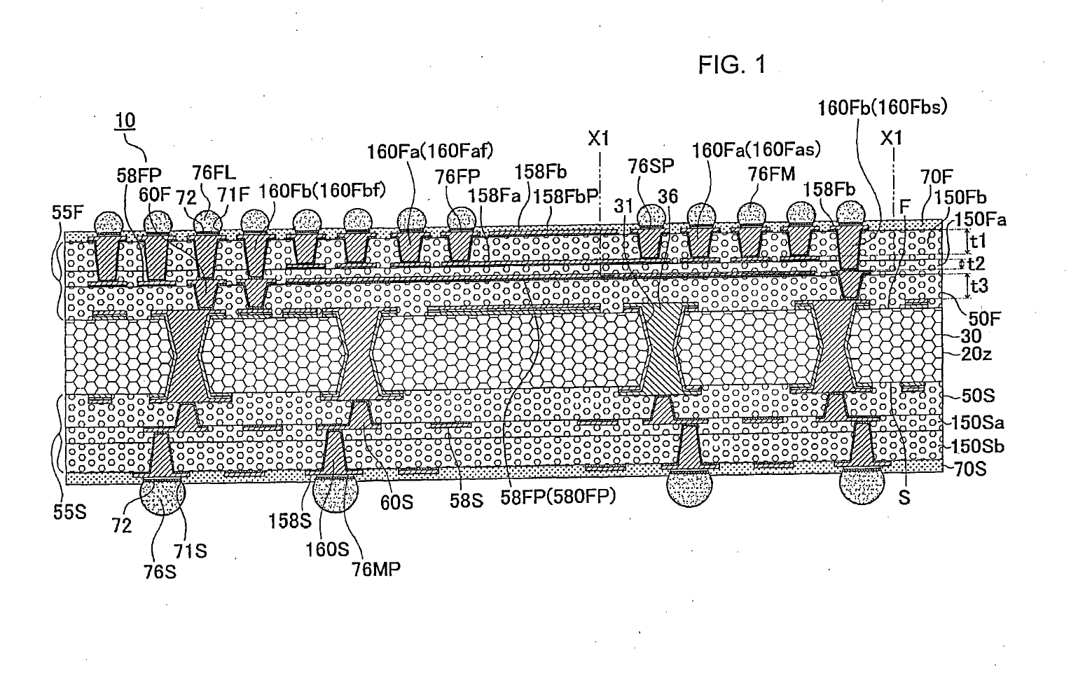

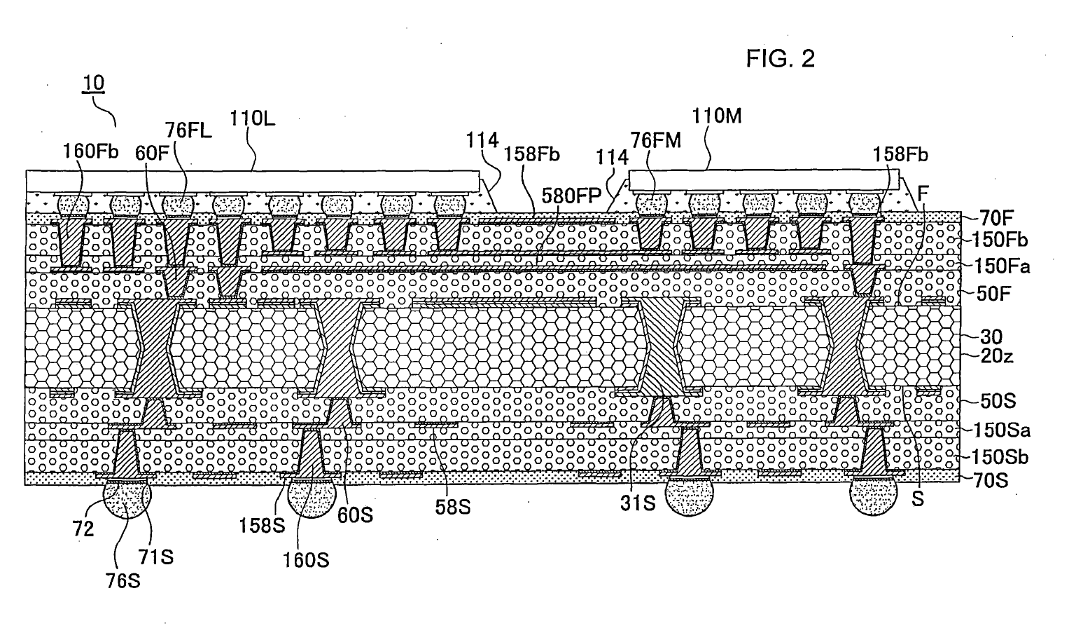

FIG. 1 shows a cross section of a package substrate of the present embodiment cut between lines (Z1) and (Z1) in FIG. 10(A). FIG. 2 shows a cross section of an application example of the present embodiment cut between lines (Z2) and (Z2) shown in FIG. 10(B).

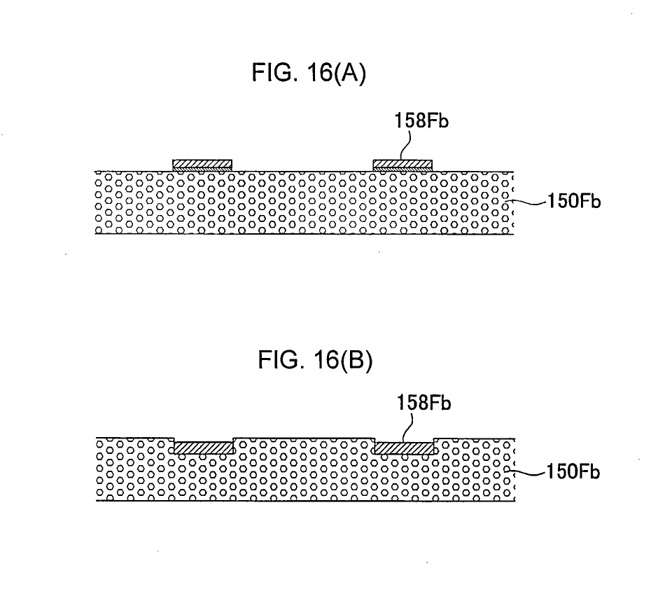

As shown in FIG. 1, the package substrate of the present embodiment has outermost conductive layer (158Fb) which includes pads for mounting an electronic component. The package substrate further contains outermost interlayer resin insulation layer (150Fb) which supports outermost conductive layer (158Fb). FIGS. 16(A) and 16(B) show examples of pads for mounting an electronic component that are provided in a package substrate of the present embodiment. FIGS. 16(A) and 16(B) each show cross sections of outermost conductive layer (158Fb) and outermost interlayer resin insulation layer (150Fb). FIG. 16(A) shows an example where an outermost conductive layer including first pad (76FP) and second pad (76SP) is formed on an outermost interlayer resin insulation layer. FIG. 16(B) shows an example where an outermost conductive layer including a first pad and a second pad is formed in a recessed portion of an outermost interlayer resin insulation layer.

In the present embodiment, first via conductor (160Faf) connected to a first pad and second via conductor (160Fas) connected to a second pad are formed in the outermost interlayer resin insulation layer. The first via conductor is preferred to be formed directly under the first pad. The second via conductor is preferred to be formed directly under the second pad.

First conductive layer (158Fa) including multiple first conductive circuits is formed under the outermost interlayer resin insulation layer. A first pad and a second pad are connected by a first conductive circuit. Namely, transmitting/receiving signals and the like between a first electronic component and a second electronic component is carried out through the first conductive layer. All of the first conductive circuits are each set to connect a first pad and a second pad. Conductive circuits formed on the same plane as the first conductive circuits are all included in the first conductive layer. The first conductive layer is an exclusive wiring layer for transmitting/receiving signals between a first electronic component and a second electronic component. The first conductive layer contains no conductive circuits except for conductive circuits (signal lines) for transmitting/receiving signals between a first electronic component and a second electronic component. The first conductive layer works as an exclusive wiring layer for data transmission between a first electronic component and a second electronic component.

Generally speaking, 1-bit data are transmitted through a signal line (one first conductive circuit). Commands and data used in electronic devices such as a personal computer are each composed of 1 byte (8 bits). If signal lines have different widths and thicknesses, electrical characteristics such as transmission speed will differ between signal lines. Thus, signal transmission time per byte may differ. Signal transmission failure or delay in signal transmission is thought to occur. Differences in transmission time per bit may occur within one byte. In addition, it is thought that variations in the widths and thicknesses of signal lines may result in a signal line with a slow transmission speed. Because of such a slow signal line, the transmission process is thought to be delayed.

An exclusive wiring layer is formed in the present embodiment. Thus, when a conductive layer that includes signal lines (exclusive wiring layer) is formed, manufacturing conditions are determined based on the width and thickness of signal lines. Accordingly, widths and thicknesses of signal lines of the present embodiment show few variations. Transmission speed in each signal line will be substantially the same. Thus, signals are processed appropriately. Even with a greater amount of data, no delay occurs in processing signals. Depending on the functions of an electronic component, exclusive wiring layers can be formed in multiple layers in the package substrate of the present embodiment. However, if multiple exclusive wiring layers are formed, differences in thicknesses and widths of signal lines are thought to increase. Thus, to reduce variations in transmission time between electronic components, the number of exclusive wiring layers is preferred to be one. However, even if exclusive wiring layers are formed in different layers, since each of such layers includes only data transmission wiring, differences in transmission time are small. One conductive layer includes all the conductive circuits sandwiched between two interlayer resin insulation layers. However, circuits such as a dummy conductor that does not transmit signals or power do not count as conductive circuits.

Inner interlayer resin insulation layer (150Fa) is formed under the outermost interlayer resin insulation layer and the first conductive layer (exclusive wiring layer). The outermost interlayer resin insulation layer and the first conductive layer (exclusive wiring layer) are supported by the inner interlayer resin insulation layer. In FIG. 1, conductive circuits sandwiched by the inner interlayer resin insulation layer and the outermost interlayer resin insulation layer are all first conductive circuits. The outermost interlayer resin insulation layer is preferred to be formed directly on the exclusive wiring layer and inner interlayer resin insulation layer. The distance between an electronic component and the exclusive wiring layer is reduced.

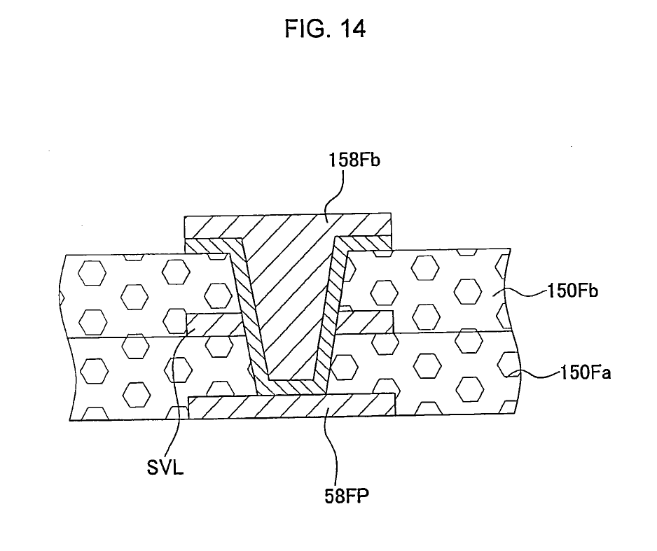

Second conductive layer (58FP) which includes multiple second conductive circuits is formed under the inner interlayer resin insulation layer. Power to an electronic component is supplied through the second conductive layer. First pads and second pads include pads connected to the second conductive layer. The second conductive layer and the pads connected to the second conductive layer are connected through skip-via conductors (160Fb). Skip-via conductor (160Fb) is formed in via-conductor opening (151Fb) which penetrates through both outermost interlayer resin insulation layer (150Fb) and inner interlayer resin insulation layer (150Fa) and reaches second conductive layer (58FP). Skip-via conductor (160Fb) penetrates through both the outermost interlayer resin insulation layer and the inner interlayer resin insulation layer. As shown in FIG. 14, a skip-via conductor may have land (SVL) of the skip-via conductor under the outermost interlayer resin insulation layer. However, the land of a skip-via conductor is independent and is not connected to the first conductive layer. Such a land does not count as a first conductive circuit. Since the skip-conductor land formed under the outermost interlayer resin insulation layer is formed in the same layer as the first conductive layer, the region for forming the first conductive layer is reduced. From such a viewpoint, it is preferred that no skip-via-conductor land be formed under the outermost interlayer resin insulation layer. The first conductive layer is formed on inner interlayer resin insulation layer (150Fa).

Since first conductive layer (158Fa) is an exclusive wiring layer, no via conductor except for a skip-via conductor is present to penetrate through the inner interlayer resin insulation layer. The package substrate of the present embodiment does not have a via conductor that penetrates only through the inner interlayer resin insulation layer. Thus, the area of the first conductive layer for forming first conductive circuits increases. More first conductive circuits are formed in the first conductive layer, allowing a high functional electronic component to be mounted on the package substrate of the present embodiment. An exclusive wiring layer is formed in a single layer. Data transmission speed increases.

The thickness of the conductive circuits in the exclusive wiring layer (first conductive layer) is less than either of the thickness of the outermost conductive layer and the thickness of the second conductive layer. The thickness of the outermost conductive layer is substantially the same as that of the second conductive layer. For example, the thickness of the first conductive layer is 3 μm or greater, which is no greater than ½ the thickness of the outermost conductive layer. The thickness of the first conductive layer is approximately 5 μm, for example, and the respective thicknesses of the outermost conductive layer and the second conductive layer are approximately 10 μm. By so setting, fine conductive circuits are formed in an exclusive wiring layer. A highly functional electronic component can be mounted on the package substrate.

The width of a first conductive circuit is less than the width of a conductive circuit included in the outermost conductive layer or the second conductive layer. Here, the width of a conductive circuit indicates the width of the thinnest conductive circuit in each conductive layer. The width of a first conductive circuit is ½ to ⅔ the width of a conductive circuit included in the outermost conductive layer or the second conductive layer. For example, the width of a first conductive circuit is approximately 5 μm, and the width of a conductive circuit included in the outermost conductive layer or second conductive layer is approximately 9 μm. When a conductive circuit is cut with a plane perpendicular to the progressive direction of the conductive circuit, the width of the conductive circuit is defined as the smallest distance among the distances between opposing walls.

The distance (width) of space between adjacent first conductive circuits is less than the distance of space between adjacent second conductive circuits. The distance of space between adjacent first conductive circuits is ½ to ⅔ the distance of space between adjacent second conductive circuits. For example, the distance of space between adjacent first conductive circuits is approximately 5 μm, and the distance of space between adjacent second conductive circuits is approximately 12 μm. Here, the distance of space indicates the narrowest distance of space in each conductive layer. The distance of space and the distance between adjacent conductive circuits are the same. Signal lines are preferred to be strip lines or microstrip lines. When signal lines are strip lines, signal lines are sandwiched between the outermost conductive layer and the second conductive layer.

The package substrate of the present embodiment has an exclusive wiring layer, an outermost interlayer resin insulation layer formed on the exclusive wiring layer, an outermost conductive layer formed on the outermost interlayer resin insulation layer and including pads for mounting multiple electronic components, and via conductors penetrating through the outermost interlayer resin insulation layer and connecting pads and the exclusive wiring layer. Pads include first pads for mounting a first electronic component and second pads for mounting a second electronic component. First pads include a first pad connected to the exclusive wiring layer and another first pad connected to a conductive layer other than the exclusive wiring layer. Second pads include a second pad connected to the exclusive wiring layer and another second pad connected to a wiring layer other than the exclusive wiring layer. The pad connected to a layer other than the exclusive wiring layer is connected to a skip-via conductor. A first pad connected to the exclusive wiring layer, a signal line in the exclusive wiring layer, and a second pad connected to the exclusive wiring layer form a closed circuit.

The package substrate of the present embodiment may further include a second conductive layer, an inner interlayer resin insulation layer on the second conductive layer, and a skip-via conductor penetrating through both the outermost interlayer resin insulation layer and the inner interlayer resin insulation layer. The exclusive wiring layer is formed on the inner interlayer resin insulation layer. The exclusive wiring layer is sandwiched between the outermost interlayer resin insulation layer and the inner interlayer resin insulation layer.

The package substrate of the present embodiment may include a core substrate with a conductive layer. In such a case, the inner interlayer resin insulation layer is formed on the core substrate, and the conductive layer of the core substrate corresponds to the second conductive layer. Furthermore, the package substrate of the present embodiment may include a buildup layer between the core substrate and the inner interlayer resin insulation layer. FIG. 1 shows an example where a buildup layer is formed with an interlayer resin insulation layer and a conductive layer. Conductive layer (58FP), sandwiched between interlayer resin insulation layer (50F) on the core substrate and inner interlayer resin insulation layer (150Fa), corresponds to the second conductive layer. The buildup layer includes an interlayer resin insulation layer and a conductive layer, and the interlayer resin insulation layer and the conductive layer are alternately laminated. A package substrate with a core substrate and its manufacturing method are described in JP 2007-227512A, for example. The entire contents of this publication are incorporated herein by reference.

It is an option to form the package substrate of the present embodiment as a coreless substrate. A coreless substrate includes an interlayer resin insulation layer and a conductive layer, which are laminated alternately. A coreless substrate and its manufacturing method are shown in JP 2005-236244A, for example. The entire contents of this publication are incorporated herein by reference. At least one of the conductive layers is set as an exclusive wiring layer. The thickness of each interlayer resin insulation layer of a coreless substrate is 30 μm to 60 μm.

Package substrate 10 shown in FIG. 1 has core substrate 30. Core substrate 30 has insulative substrate (20z) with first surface (F) and second surface (S) opposite the first surface. Conductive layer (34F) is formed on first surface (F) of insulative substrate (20z), and conductive layer (34S) is formed on second surface (S). Insulative substrate (20z) has multiple penetrating holes 31; through-hole conductor 36 is formed in penetrating hole 31 and connects conductive layer (34F) and conductive layer (34S). Penetrating hole 31 for a through-hole conductor is shaped like an hourglass.

First buildup layer (55F) is formed on first surface (F) of core substrate 30. The first surface of the core substrate corresponds to the first surface of the insulative substrate. First buildup layer (55F) has interlayer resin insulation layer (upper interlayer resin insulation layer) (50F) formed on core substrate 30, second conductive layer (58FP) on interlayer resin insulation layer (50F), and via conductors (60F) which penetrate interlayer resin insulation layer (50F) and connect second conductive layer (58FP) and conductive layer (34F).

The first buildup layer further includes inner interlayer resin insulation layer (150Fa) formed on interlayer resin insulation layer (50F) and second conductive layer (58FP), and first conductive layer (158Fa) formed on inner interlayer resin insulation layer (150Fa). The first conductive layer is set as an exclusive wiring layer. There is no via conductor that penetrates through only inner interlayer resin insulation layer (150Fa). The first buildup layer further includes uppermost interlayer resin insulation layer (outermost interlayer resin insulation layer) (150Fb) formed on inner interlayer resin insulation layer (150Fa) and first conductive layer (158Fa), uppermost conductive layer (outermost conductive layer) (158Fb) formed on uppermost interlayer resin insulation layer (150Fb), via conductors (uppermost via conductors) (160Fa) penetrating through the uppermost interlayer resin insulation layer and connecting the uppermost conductive layer and the first conductive layer, and skip-via conductors (160Fb) penetrating through both the uppermost interlayer resin insulation layer and the inner interlayer resin insulation layer and connecting the uppermost conductive layer and the second conductive layer. The uppermost conductive layer includes first pads (76FP) for mounting a first electronic component and second pads (76SP) for mounting a second electronic component. Uppermost via conductors include first via conductor (uppermost first via conductor) (160Faf) connecting a first pad and the first conductive layer, and second via conductor (uppermost second via conductor) (160Fas) connecting a second pad and the first conductive layer. Skip-via conductors include first skip-via conductor (160Fbf) connecting a first pad and the second conductive layer, and second skip-via conductor (160Fbs) connecting a second pad and the second conductive layer.

When multiple exclusive wiring layers are formed, such exclusive wiring layers are preferred to be formed only in the first buildup layer.

Second buildup layer (55S) is formed on second surface (S) of core substrate 30. Second buildup layer (55S) includes an interlayer resin insulation layer and a conductive layer, which are laminated alternately. The first buildup layer and the second buildup layer are preferred to be set symmetrical by sandwiching the core substrate.

Solder-resist layer (70F) with openings (71F) is formed on first buildup layer (55F), and solder-resist layer (70S) with openings (71S) is formed on second buildup layer (55S). First pads (76FP) and second pads (76SP) are exposed through openings (71F) of solder-resist layer (70F) on first buildup layer (55F). Solder bumps (first solder bumps) (76FL) are formed on first pads, and solder bumps (second solder bumps) (76FM) are formed on second pads. The melting point of the first solder bumps is preferred to be different from that of the second solder bumps. By so setting, mounting yield and connection reliability will be enhanced. Also, it is easier to switch electronic components. On pads (76MP) exposed from openings (71S) of solder-resist layer (70S) on second buildup layer (55S), solder bumps (third solder bumps) (76S) are formed for connection with a motherboard. Metal film 72 made of Ni/Au or Ni/Pd/Au is formed on pads (76FP, 76SP, 76MP). As shown in FIGS. 2 and 10(B), IC chip (110L) is mounted on solder bumps (76FL) for mounting an IC chip, and memory (110M) is mounted on solder bumps (76FM) for mounting a memory. Package substrate 10 is mounted on a motherboard through solder bumps (76S) formed on the second buildup layer. The melting points of the first solder bumps, the second solder bumps and the third solder bumps are preferred to be different from each other. Mounting yield and connection reliability are high.

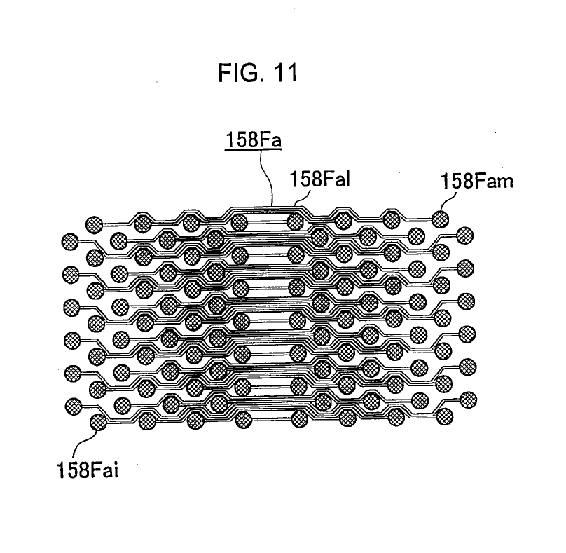

FIG. 11 is a plan view showing part of the exclusive layer (first conductive layer) (158Fa). The circular-shaped conductors in the drawing are pads. Pads on the left are first via-conductor pads (158Fai), and pads on the right are second via-conductor pads (158Fam). First via conductor (160Faf) is formed on a first via-conductor pad, and second via conductor (160Fas) is formed on a second via-conductor pad. A first conductive circuit includes a first via-conductor pad (158Fai), second via-conductor pad (158Fam), and connecting wiring (158Fal) that connects first via-conductor pad (158Fai) and second via-conductor pad (158Fam). In the package substrate of the first embodiment, all the data transmissions between a first electronic component such as a logic chip and a second electronic component such as a memory chip are conducted through the first conductive layer.

First conductive circuit (158Fa) is formed as a stripline, sandwiched by planar layer (158FbP) which is included in the uppermost conductive layer and planar layer (580FP) which is included in the second conductive layer. Transmission characteristics of the first conductive circuit are improved.

The thickness of the inner interlayer resin insulation layer is different from the thickness of other interlayer resin insulation layers. Among interlayer resin insulation layers, interlayer resin insulation layers except for the inner interlayer resin insulation layer have the same thickness. The thickness of an interlayer resin insulation layer is equal to the distance between adjacent conductive layers. In FIG. 1, thickness (t1) of outermost interlayer resin insulation layer (150Fb) is equal to thickness (t3) of upper interlayer resin insulation layer (50F). Thicknesses (t1, t3) of interlayer resin insulation layers except for the inner interlayer resin insulation layer are 15 μm to 40 μm. Thickness (t2) of the inner interlayer resin insulation layer is 7.5 μm to 20 μm. Thickness (t2) of the inner interlayer resin insulation layer is ½ to ⅔ the respective thicknesses (t1, t3) of other interlayer resin insulation layers. Fine skip-via conductors are formed. The area for forming the first conductive layer will not be reduced because of skip-via conductors. The size of the package substrate is reduced. For example, thickness (t2) of inner interlayer resin insulation layer (150Fa) is 13 μm, and the thickness of the interlayer resin insulation layers except for the inner interlayer resin insulation layer is 35 μm each.

Since the exclusive wiring layer is formed directly under outermost interlayer resin insulation layer (150Fb) in the package substrate of the first embodiment, the wiring distance of the electronic component is shortened. Signal transmission speed increases between electronic components. Since the package substrate of the present embodiment has an exclusive wiring layer, the electrical characteristics of each signal line become similar. Signal transmission time per byte becomes uniform. Signals are transmitted appropriately even at high speed. Signal processing is not delayed even with an increase in the amount of data. The package substrate of the present embodiment does not include a via conductor that penetrates only through the inner interlayer resin insulation layer. The package substrate of the present embodiment includes a skip-via conductor that penetrates through both an inner interlayer resin insulation layer and the interlayer resin insulation layer on the inner interlayer resin insulation layer. The size of the package substrate is reduced. Signal transmission time per byte becomes uniform. Signals are transmitted appropriately even at high speed. Signal processing is not delayed even with an increase in the amount of data.

### Method for Manufacturing Package Substrate of the First Embodiment

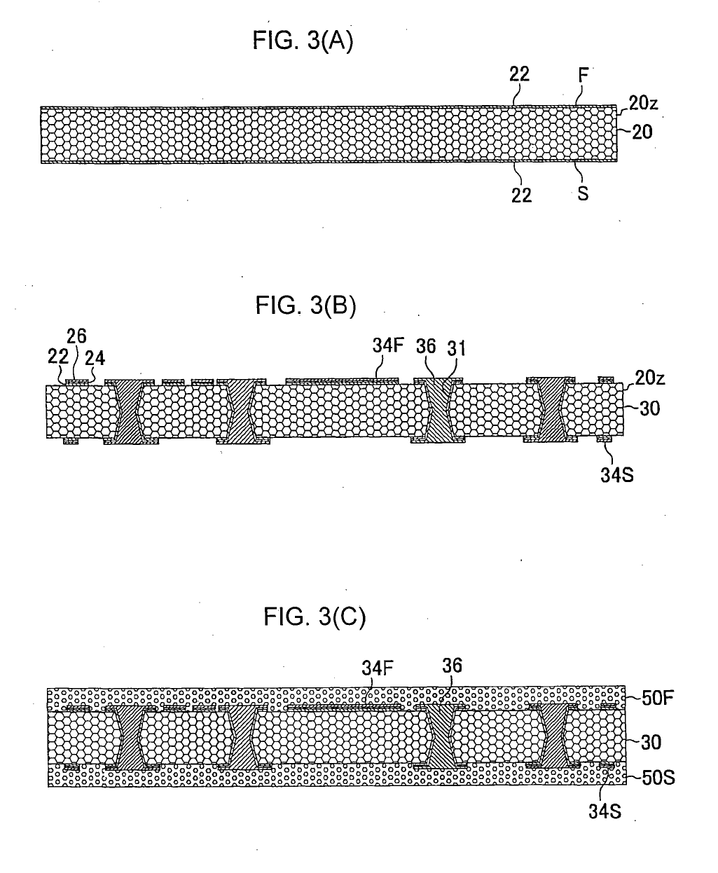

FIGS. 3 to 9 show a method for manufacturing package substrate 10 of the first embodiment.

(1) Starting substrate 20 with first surface (F) and second surface (S) opposite the first surface is prepared. The starting substrate is preferred to be a double-sided copper-clad laminate. A double-sided copper-clad laminate is formed with insulative substrate (20z) having first surface (F) and second surface (S) opposite the first surface along with metal foils (22, 22) laminated on both surfaces (FIG. 3(A)). The starting substrate of the first embodiment is a double-sided copper-clad laminate. A black-oxide treatment is conducted on surfaces of copper foils 22.

Insulative substrate (20z) is made up of resin and reinforcing material. Examples of reinforcing material are glass cloth, aramid fiber and fiberglass. Examples of resin are epoxy resin and BT (bismaleimide triazine) resin.

(2) The double-sided copper-clad laminate is processed to complete core substrate 30, which includes upper conductive layer (34F) and lower conductive layer (34S) each made of metal foil 22, electroless plated film 24 and electrolytic plated film 26, and through-hole conductor 36 formed in penetrating hole 31 (FIG. 3(B)). The first surface of core substrate 30 corresponds to the first surface of insulative substrate (20z), and the second surface of core substrate 30 corresponds to the second surface of insulative substrate (20z). Core substrate 30 is manufactured by a method disclosed in U.S. Pat. No. 7,786,390, for example.

(3) Upper interlayer resin insulation layer (50F) is formed on first surface (F) of core substrate 30. Lower interlayer resin insulation layer (50S) is formed on second surface (S) of the core substrate (FIG. 3(C)). The interlayer resin insulation layers contain thermosetting resin such as epoxy resin and inorganic particles of silica and the like. The interlayer resin insulation layers may further contain reinforcing material such as glass cloth. The approximate thickness of interlayer resin insulation layers (50F, 50S) is 35 μm each.

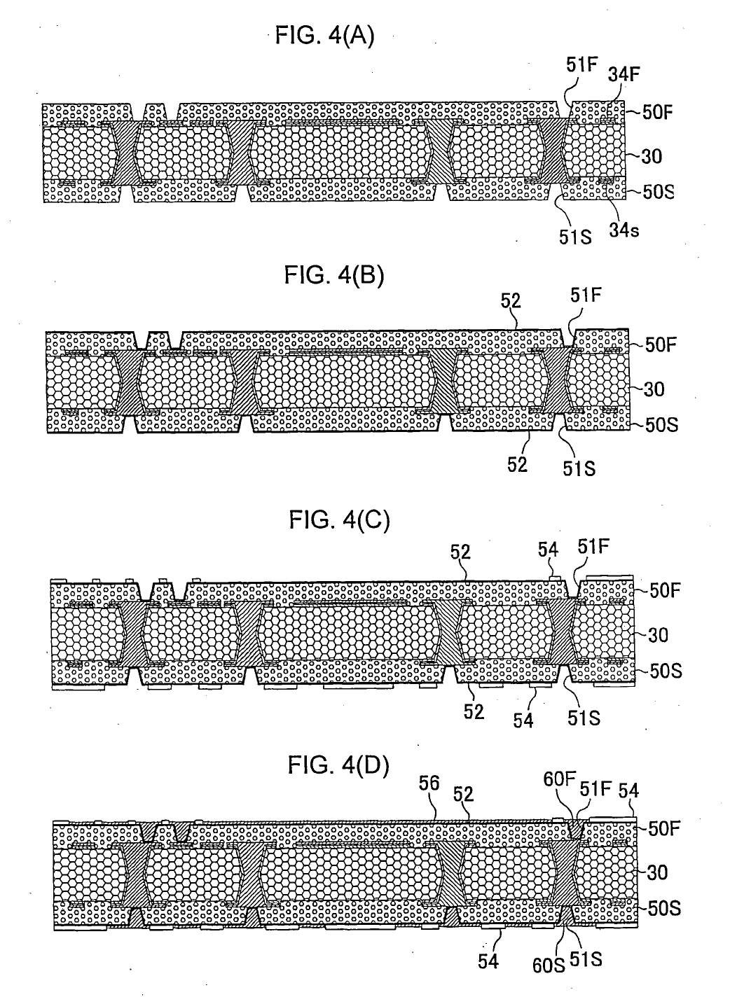

(4) Next, using a CO2 gas laser, via-conductor openings (51F, 51S) are respectively formed in interlayer resin insulation layers (50F, 50S) (FIG. 4(A)).

(5) Electroless copper-plated films (52, 52) are formed on interlayer resin insulation layers (50F, 50S) and on the inner walls of openings (51F, 51S) (FIG. 4(B)).

(6) Plating resist 54 is formed on electroless copper-plated films 52 (FIG. 4(C)).

(7) Electrolytic copper-plated film 56 is formed on electroless copper-plated film 52 exposed from plating resist 54. During that time, openings (51F, 51S) are filled with electrolytic plated film 56. Via conductors (60F, 60S) are formed (FIG. 4(D)).

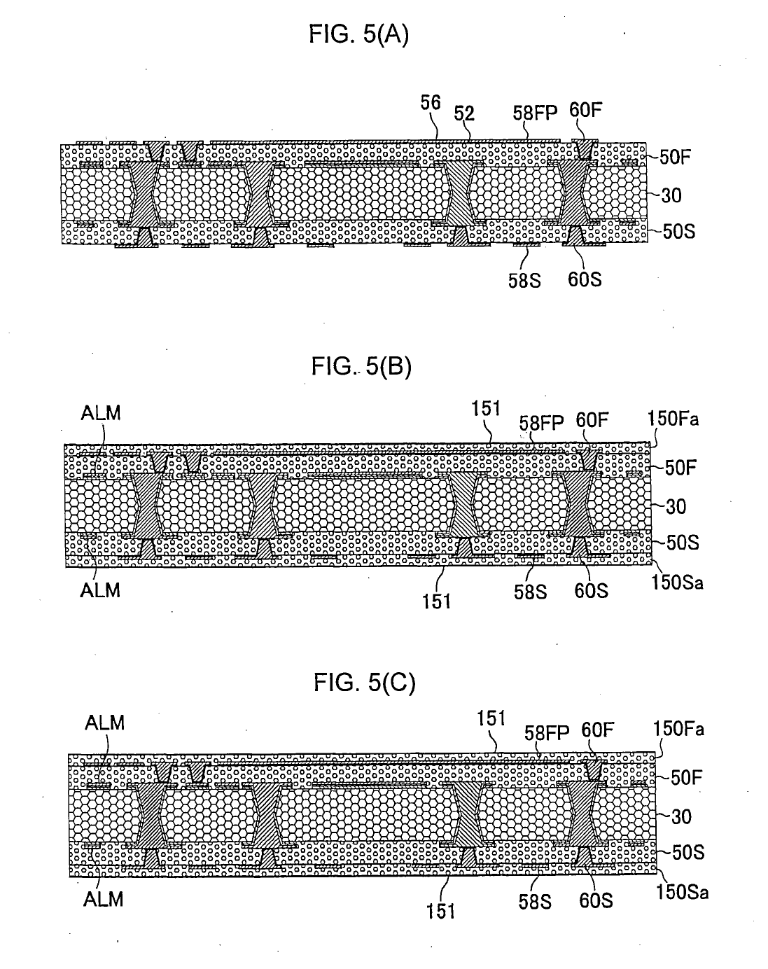

(8) Plating resist 54 is removed. Electroless plated film 52 exposed from electrolytic film 56 is removed. Second conductive layer (upper second conductive layer) (58FP) is formed on interlayer resin insulation layer (50F). Second conductive layer (lower second conductive layer) (58S) is formed on interlayer resin insulation layer (50S) (FIG. 5(A)).

(9) A B-stage resin film having a first surface and a second surface opposite the first surface is prepared. On the first surface of the resin film, seed layer 151 is formed by sputtering. The seed layer is made of copper or the like. The thickness of the seed layer (sputtered film) is 0.05 μm to 0.3 μm. The resin film with the seed layer is laminated on upper second conductive layer (58FP) and upper interlayer resin insulation layer (50F) in such a way that the second surface of the resin film faces the upper interlayer resin insulation layer (50F). Then, by curing the resin film, inner interlayer resin insulation layer (upper inner interlayer resin insulation layer) (150Fa) is formed on upper second conductive layer (58FP) and upper interlayer resin insulation layer (50F). In the present embodiment, the upper inner interlayer resin insulation layer is an interlayer resin insulation layer with a seed layer.

The package substrate of the present embodiment does not have a via conductor that penetrates only through the inner interlayer resin insulation layer. Thus, a seed layer is formed on the resin film before its lamination. Since the seed layer is formed by sputtering prior to lamination, the seed layer has a thin, uniform thickness. However, the seed layer may be formed on the inner interlayer resin insulation layer after the inner interlayer resin insulation layer has been formed. The package substrate of the present embodiment does not have a via conductor that penetrates only through the inner interlayer resin insulation layer. Therefore, even if a seed layer is formed after lamination, since it is not necessary to form the seed layer on the inner wall of a via-conductor opening, the seed layer has a thin, uniform thickness. In the same manner, inner interlayer resin insulation layer (lower inner interlayer resin insulation layer) (150Sa) is formed on lower second conductive layer (58S) and lower interlayer resin insulation layer (50S) (FIG. 5(B)). In the present embodiment, the lower inner interlayer resin insulation layer is an interlayer resin insulation layer with a seed layer. The thickness of inner interlayer resin insulation layers (150Fa, 150Sa) is 17 μm each, approximately one half the thickness of interlayer resin insulation layers (50F, 50S).

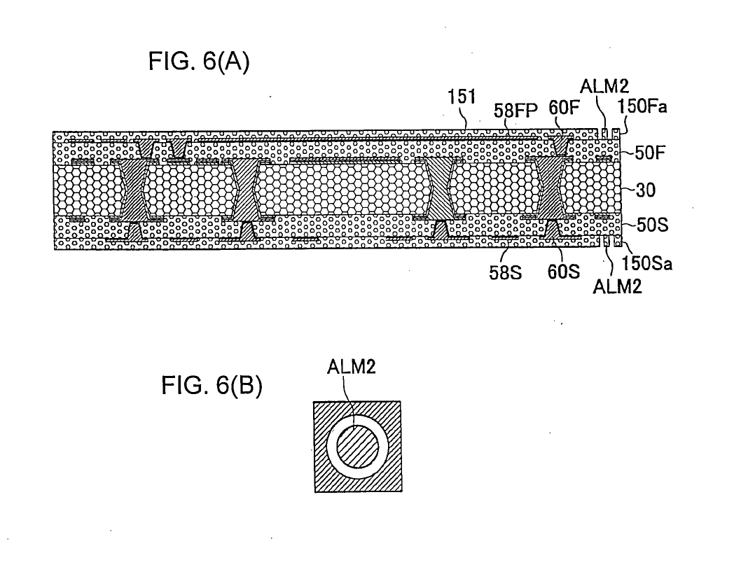

(10) Part of the seed layer formed on an inner interlayer resin insulation layer is removed. Accordingly, the seed layer on an alignment mark (ALM) formed in the second conductive layer is removed (FIG. 5(C)). At that time, the seed layer in the area for forming later-described alignment mark (ALM2) is also removed. Alignment mark (ALM2) is formed in an inner interlayer resin insulation layer based on the alignment mark in the second conductive layer (FIG. 6(A)). An example of alignment mark (ALM2) is shown in FIG. 6(B). The portions with slanting lines are the top surface of the inner interlayer resin insulation layer, and the empty portion indicates a groove. An alignment mark is formed with portions of an inner interlayer resin insulation layer and a groove formed in the inner interlayer resin insulation layer. Such an alignment mark is a ring-shaped groove formed in an inner interlayer resin insulation layer and is formed by a laser.

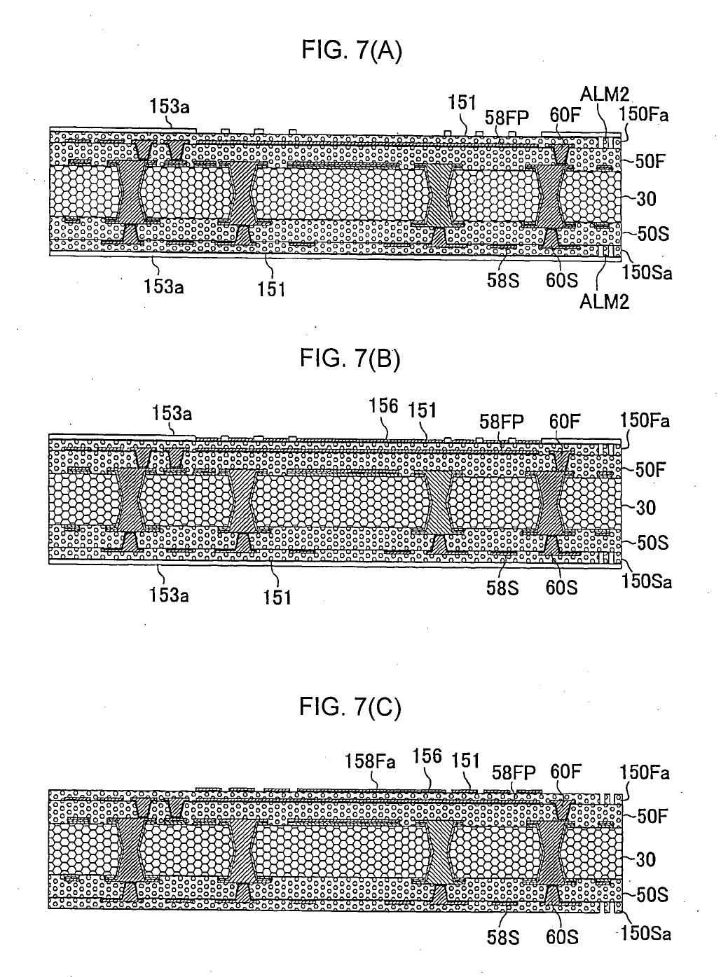

(11) Plating resist (153a) is formed on seed layer 151 based on alignment mark (ALM2) (FIG. 7(A)). Plating resist (153a) on the lower inner interlayer resin layer is formed on its entire surface.

(12) Electrolytic copper-plated layer 156 is formed on seed layer 151 exposed from plating resist (153a) (FIG. 7(B)).

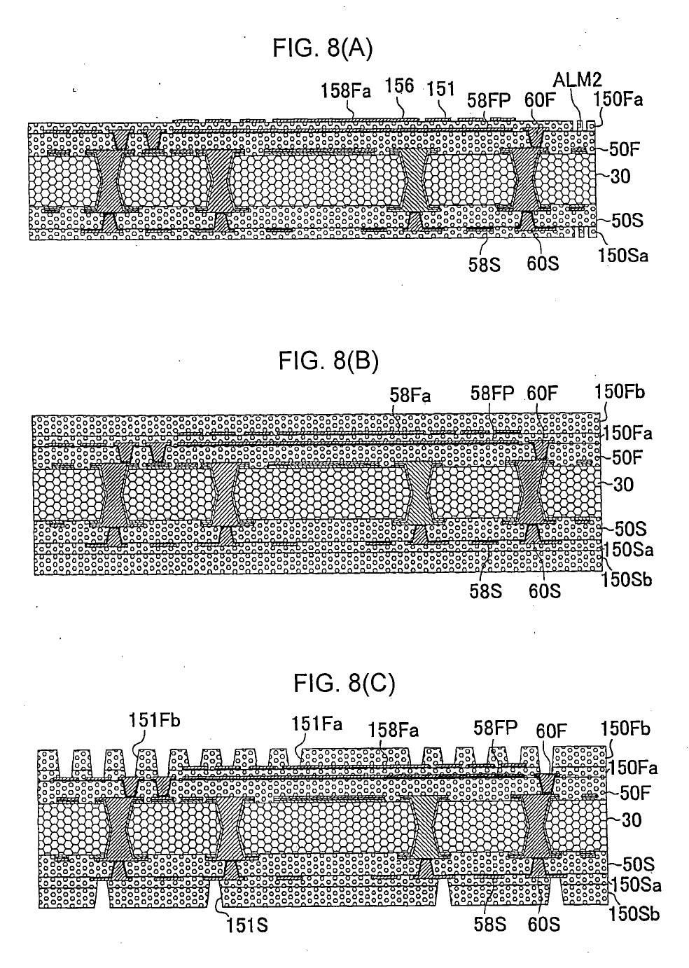

(13) Plating resist (153a) is removed (FIG. 7(C)). Seed layer 151 exposed from electrolytic copper-plated layer 156 is removed. First conductive layer (upper first conductive layer) (158Fa) made of seed layer 151 and electrolytic copper-plated layer 156 on the seed layer is formed on upper inner interlayer resin insulation layer (150Fa) (FIG. 8(A)). Part of first conductive layer (158Fa) is shown in FIG. 11. FIG. 11 is a plan view. The L/S (line/space) of first conductive circuits included in the first conductive layer is 5/5 μm, for example. First via-conductor pads (158Fai) and second via-conductor pads (158Fam) are also formed at the same time. The first conductive layer has a first alignment mark formed at the same time as those via-conductor pads. The first alignment mark is not shown in the drawings. When the resin film for forming the lower inner interlayer resin insulation layer is a resin film with an attached seed layer, the seed layer is removed. Since the seed layer is completely removed, the inner interlayer resin insulation layer of the second buildup layer is preferred to be formed using a resin film without an attached seed layer. No conductive layer is formed on the lower inner interlayer resin insulation layer.

(14) On the upper inner interlayer resin insulation layer and on the upper first conductive layer (exclusive wiring layer), outermost interlayer resin insulation layer (upper outermost interlayer resin insulation layer) (150Fb) is formed. On the lower inner interlayer resin insulation layer, outermost interlayer resin insulation layer (lower outermost interlayer resin insulation layer) (150Sb) is formed (FIG. 8(B)). The thickness of interlayer resin insulation layers (150Fb, 150Sb) is the same as the thickness of interlayer resin insulation layers (50F, 50S).

(15) Based on the first alignment mark, first openings (151Fa) which penetrate through upper outermost interlayer resin insulation layer (150Fb) and reach first conductive layer (158Fa) as well as second openings (151Fb) which penetrate through both upper outermost interlayer resin insulation layer (150Fb) and upper inner interlayer resin insulation layer (150Fa) and reach upper second conductive layer (58FP) are formed using a laser. Openings (151S) which penetrate through both lower outermost interlayer resin insulation layer (150Sb) and lower inner interlayer resin insulation layer (150Sa) and reach lower second conductive layer (58S) are formed (FIG. 8(C)).

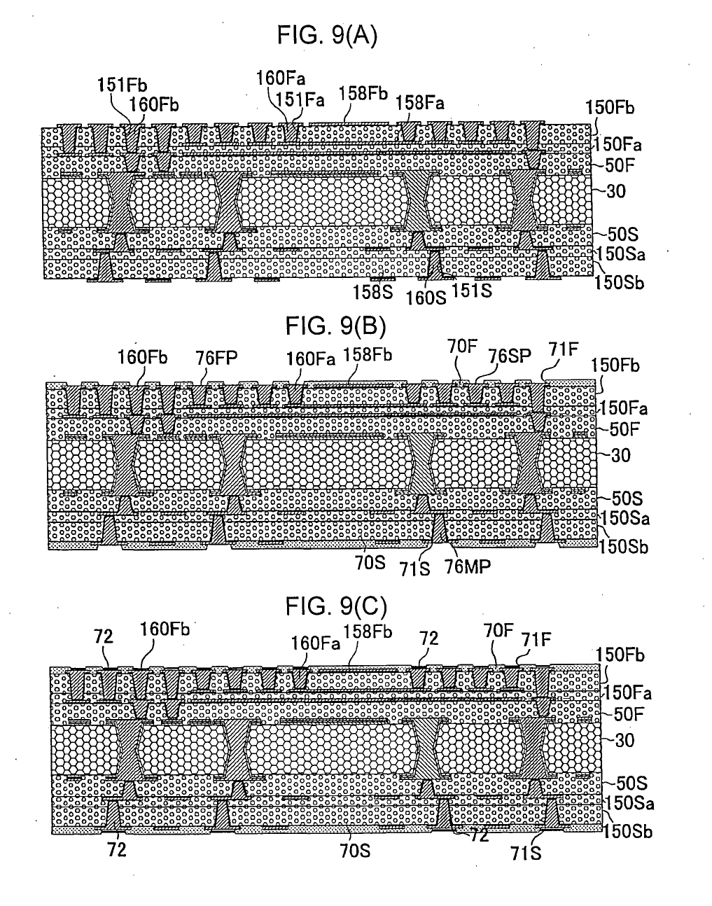

(16) Using a known semi-additive method, via conductors (160Fa, 160Fb, 160S) are formed in via-conductor openings (151Fa, 151Fb, 151S). Also, outermost conductive layers (158Fb, 158S) are formed (FIG. 9(A)). Via conductors (160Fb, 160S) are skip-via conductors, each penetrating through both an outermost interlayer resin insulation layer and inner interlayer resin insulation layer, and connecting the outermost conductive layer and the second conductive layer. The outermost conductive layer and the second conductive layer include a planar layer sandwiching the first conductive circuits. The outermost conductive layer and the first conductive layer are connected by via conductors (160Fa). The uppermost conductive layer includes a first pad group and a second pad group. The second pad group includes a first group, second group, third group and fourth group. As shown in FIG. 10, the second pad group surrounds the first pad group. Each group of the second pad group is formed on each of the outer sides of the first pad group.

(17) Upper solder-resist layer (70F) having openings (71F) is formed on the first buildup layer, and lower solder-resist layer (70S) having openings (71S) is formed on the second buildup layer (FIG. 9(B)). The top surfaces of first pads (76FP) and second pads (76SP) are exposed from openings (71F) of first solder-resist layer (70F). Meanwhile, the top surfaces of the conductive layer and via lands exposed from openings (71S) of second solder-resist layer (70S) work as pads (76MP) for connection with a motherboard.

(18) A nickel-plated layer is formed on pads (76FP, 76SP, 76MP), and a gold-plated layer is further formed on the nickel-plated layer (FIG. 9(C)). Instead of nickel-gold layers, nickel-palladium-gold layers or an OSP film may also be formed.

(19) Solder balls are loaded on pads (76FP, 76SP, 76MP), and a reflow is conducted to form solder bumps (76FM, 76FL, 76S). Package substrate 10 is completed (FIG. 1).

(20) Logic IC chip (110L) is mounted on solder bumps (76FL) on first pads, and memory (110M) is mounted on solder bumps (76FM) on the second pads (FIG. 2, FIG. 10(B)). Underfill 114 is filled between the package substrate and IC chip (110L) as well as memory (110M) (FIG. 2).

In a method for manufacturing a package substrate of the first embodiment, first conductive layer (158Fa) is formed using the seed layer of a resin film with an attached seed layer. Since a seed layer is formed on a single film, the thickness of the seed layer or variations of its thickness are minimized. Also, sputtering can be used for forming a seed layer. Since a first conductive layer is an exclusive wiring layer for transmitting data, the thickness of the first conductive layer is reduced. Since the seed layer is thin, a smaller amount of etching is necessary when removing the seed layer to form conductive circuits. Accordingly, fine conductive circuits are formed in the first conductive layer. For example, the first conductive layer has fine signal lines with an L/S of 8 μm/8 μm or less. In the first embodiment, since no conductive layer is present on the lower inner interlayer resin insulation layer, it is an option not to form the lower inner interlayer resin insulation layer. In such a case, to reduce the warping of the package substrate, the thickness of that one interlayer resin insulation layer included in the second buildup layer is preferred to be greater than the thickness of any other interlayer resin insulation layer. Such a thickness is calculated by adding the thickness of the upper inner interlayer resin insulation layer and the thickness of an interlayer resin insulation layer other than the upper inner interlayer resin insulation layer.

### Second Embodiment

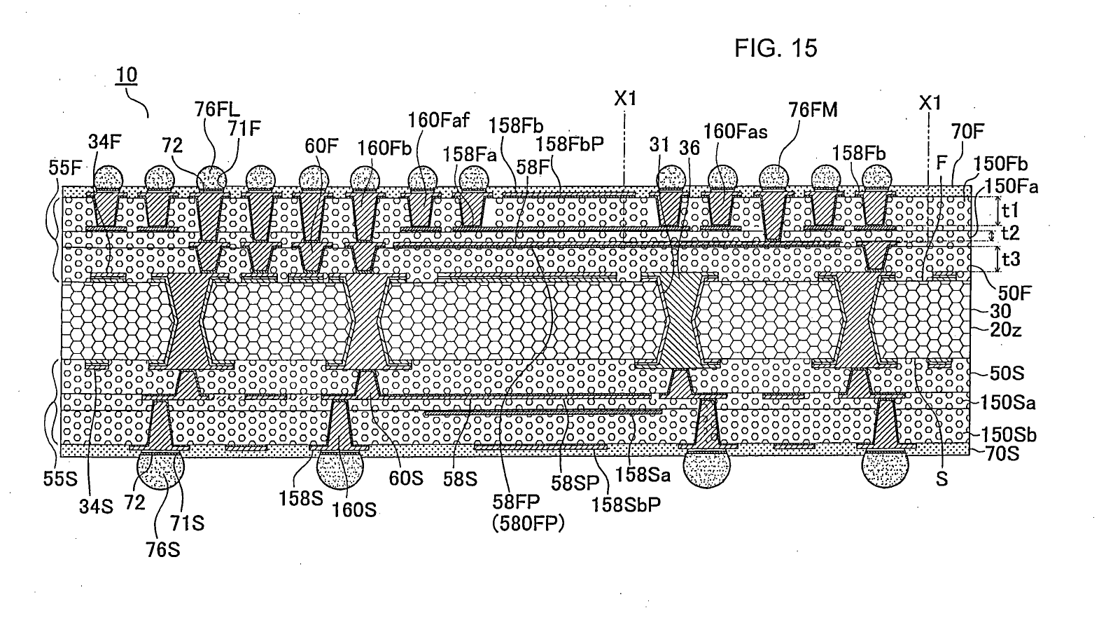

FIG. 15 shows a package substrate according to a second embodiment. The package substrate of the second embodiment has multiple exclusive wiring layers.

In the second embodiment, second exclusive wiring layer (158Sa) is formed on the lower inner interlayer resin insulation layer. According to the present embodiment, an exclusive wiring layer may be formed in each of the different layers. In the second embodiment, a second exclusive wiring layer is formed in the second buildup layer, but the second exclusive wiring layer may also be formed in the first buildup layer. Since the first buildup layer is closer to electronic components, the second exclusive wiring layer is preferred to be formed in the first buildup layer.

### Third Embodiment

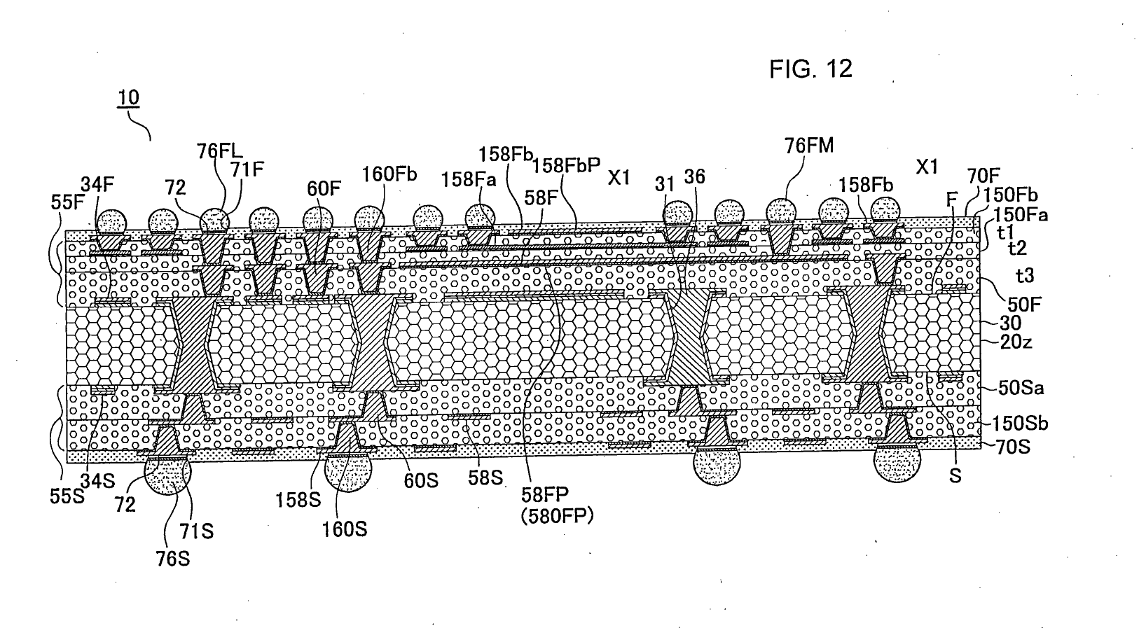

FIG. 12 shows a package substrate according to a third embodiment. In the third embodiment, a second buildup layer does not have an inner interlayer resin insulation layer. The outermost interlayer resin insulation layer (150Sb) of the second buildup layer is formed at the same time as outermost interlayer resin insulation layer (150Fa) of the first buildup layer. The thickness of interlayer resin insulation layer (150Sb) is obtained by adding the thickness of interlayer resin insulation layer (150Fa) and the thickness of interlayer resin insulation layer (150Fb).

### Fourth Embodiment

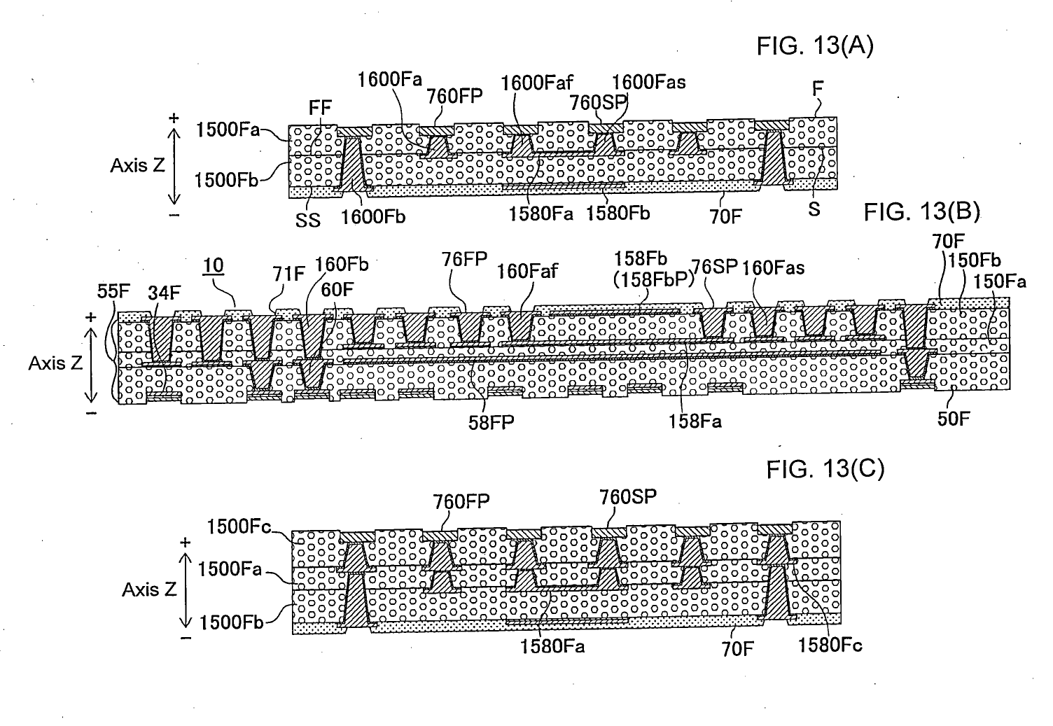

An example of a coreless substrate is shown in FIG. 13. Such a substrate is formed by a method described in JP 2005-236244A, for example. The entire contents of this publication are incorporated herein by reference. An axis Z is shown in FIG. 13; (+) indicates the upper side and (−) indicates the lower side. The mounting surface is the upper surface shown in FIG. 13. A coreless substrate can also have a second exclusive wiring layer. The coreless substrate shown in FIG. 13 includes alternately laminated multiple interlayer resin insulation layers and multiple conductive layers. Among the multiple interlayer resin insulation layers, at least one interlayer resin insulation layer is for an exclusive wiring layer (exclusive interlayer resin insulation layer). An exclusive wiring layer is formed on the exclusive interlayer resin insulation layer. Also, among the multiple conductive layers, at least one conductive layer is for an exclusive wiring layer. The exclusive wiring layer is formed on the exclusive interlayer resin insulation layer. As shown in FIG. 13(A), when pads (760FP, 760SP) for mounting electronic components are embedded in the outermost interlayer resin insulation layer, a coreless substrate is formed by alternately laminating an interlayer resin insulation layer and a conductive layer on those pads. Thus, outermost interlayer resin insulation layer (uppermost interlayer resin insulation layer) (1500Fa) can be used as an exclusive interlayer resin insulation layer. In such a case, the uppermost interlayer resin insulation layer has first surface (F) and second surface (S) opposite the first surface. On the first surface of the uppermost interlayer resin insulation layer (exclusive interlayer resin insulation layer), a first pad group including multiple first pads (760FP) and a second pad group including multiple second pads (760SP) are formed. On the second surface of the uppermost interlayer resin insulation layer, exclusive wiring layer (1580Fa) is formed. Then, on the second surface of the exclusive interlayer resin insulation layer and on the exclusive wiring layer, second interlayer resin insulation layer (1500Fb) having first surface (FF) and second surface (SS) opposite the first surface is formed. The exclusive wiring layer is sandwiched by second surface (S) of exclusive interlayer resin insulation layer (1500Fa) and first surface (FF) of the second interlayer resin insulation layer. Second conductive layer (1580Fb) is formed on the second surface of the second interlayer resin insulation layer. Pads connected to the exclusive wiring layer are connected to the exclusive wiring layer through via conductors (1600Fa) that penetrate through the exclusive interlayer resin insulation layer. The same as in the first embodiment, via conductors (1600Fa) include via conductor (1600Faf) connected to a first pad and via conductor (1600Fas) connected to a second pad. A pad connected to the second conductive layer is connected by skip-via conductor (1600Fb) which penetrates through both exclusive interlayer resin insulation layer (1500Fa) and second interlayer resin insulation layer (1500Fb). Second conductive layer (1580Fb) shown in FIG. 13(A) corresponds to second conductive layer (58FP) of the first embodiment. Exclusive wiring layer (1580Fa) shown in FIG. 13(A) corresponds to first conductive layer (158Fa) of the first embodiment.

The coreless substrate shown in FIG. 13(B) is obtained by removing insulative substrate (20z), lower conductive layer (34S) of the core substrate, second buildup layer (55S), lower solder-resist layer (70S), metal film 72 and solder bumps (76FL, 76FM, 76S) from the package substrate of the first embodiment shown in FIG. 1. Then, as shown in FIG. 13(B), upper conductive layer (34F) of the core substrate is embedded on the lower surface of upper interlayer resin insulation layer (50F). Conductive layer (34F) includes pads for connection with another substrate such as a motherboard. It is an option for conductive layer (34F) shown in FIG. 13(B) to be formed only with pads for connection with another substrate such as a motherboard. Interlayer resin insulation layer (50F) of the coreless substrate shown in FIG. 13(B) corresponds to the lowermost interlayer resin insulation layer in the coreless substrate of the fourth embodiment. Then, conductive layer (58FP) formed on the lowermost interlayer resin insulation layer is the second conductive layer. Interlayer resin insulation layer (150Fa) formed on the lowermost interlayer resin insulation layer and on the second conductive layer is the inner interlayer resin insulation layer, and conductive layer (158Fa) formed on the inner interlayer resin insulation layer is the exclusive wiring layer. Interlayer resin insulation layer (150Fb) formed on the inner interlayer resin insulation layer and on the exclusive wiring layer is the uppermost interlayer resin insulation layer. Conductive layer (158Fb) formed on the uppermost interlayer resin insulation layer is the outermost conductive layer. The same as in the first embodiment, the outermost conductive layer has a first pad group including first pads and a second pad group including second pads. In addition, the same as in the first embodiment, coreless substrates shown in FIGS. 13(A, B and C) have first via conductors (160Faf, 1600Faf), second via conductors (160Fas, 1600Fas) and skip-via conductors (160Fb, 1600Fb),

As shown in FIG. 13(C), the coreless substrate shown in FIG. 13(A) may also include another interlayer resin insulation layer (1500Fc) and another conductive layer (1580Fc) between exclusive interlayer resin insulation layer (1500Fa) and pads (760FP, 760SP) for mounting electronic components.

When multiple second electronic components are mounted on a package substrate in each embodiment, all of the second electronic components may be the same type, or an electronic component may be different from the other multiple second electronic components. Also, a first electronic component and a second electronic component may be the same type.

It may be difficult for a multichip module substrate to increase transmission speed between electronic components.

A package substrate according to an embodiment of the present invention is capable of increasing signal transmission speed between electronic components.

A package substrate according to an embodiment of the present invention has the following: an outermost interlayer resin insulation layer with a first surface and a second surface opposite the first surface; an outermost conductive layer which is formed on the first surface of the outermost interlayer resin insulation layer and which includes a first pad group composed of multiple first pads for mounting a first electronic component as well as a second pad group composed of multiple second pads for mounting a second electronic component; a first conductive layer which is formed under the second surface of the outermost interlayer resin insulation layer and which includes multiple first conductive circuits; first via conductors which penetrate through the outermost interlayer resin insulation layer and connect the first conductive layer and the first pads; and second via conductors which penetrate through the outermost interlayer resin insulation layer and connect the first conductive layer and the second pads.

All the first conductive circuits in the first conductive layer are each set to connect a first pad of the first pad group and a second pad of the second pad group.

A method for manufacturing a package substrate according to another embodiment of the present invention includes the following: preparing a resin film with an attached seed layer; by curing the resin film, forming an inner interlayer resin insulation layer which has a first surface and a second surface opposite the first surface as well as the seed layer formed on the first surface; on the first surface of the inner interlayer resin insulation layer, forming an exclusive wiring layer for transmitting data between electronic components by a semi-additive method using the seed layer; forming an outermost interlayer resin insulation layer on the exclusive wiring layer and on the first surface of the inner interlayer resin insulation layer; forming a second conductive layer under the second surface of the inner interlayer resin insulation layer; on the outermost interlayer resin insulation layer, forming an outermost conductive layer which includes first pads for mounting a first electronic component and second pads for mounting a second electronic component; forming first via conductors which penetrate through the outermost interlayer resin insulation layer and connect the first pads and the exclusive wiring layer; forming second via conductors which penetrate through the outermost interlayer resin insulation layer and connect the second pads and the exclusive wiring layer; and forming skip-via conductors which penetrate through both the outermost interlayer resin insulation layer and the inner interlayer resin insulation layer and connect the outermost conductive layer and the second conductive layer. The exclusive wiring layer includes a signal line for data transmission between the first electronic component and the second electronic component.

Obviously, numerous modifications and variations of the present invention are possible in light of the above teachings. It is therefore to be understood that within the scope of the appended claims, the invention may be practiced otherwise than as specifically described herein.

What is claimed is:

1. A package substrate, comprising:
an outermost interlayer resin insulation layer;
an outermost conductive layer formed on a first surface of the outermost interlayer resin insulation layer and including a plurality of first pads positioned to mount a first electronic component and a plurality of second pads positioned to mount a second electronic component;
a first conductive layer including a plurality of first conductive circuits and formed on a second surface of the outermost interlayer resin insulation layer on an opposite side with respect to the first surface;
a plurality of first via conductors penetrating through the outermost interlayer resin insulation layer such that the first via conductors are connecting the first conductive layer and the first pads; and
a plurality of second via conductors penetrating through the outermost interlayer resin insulation layer such that the second via conductors are connecting the first conductive layer and the second pads,
wherein the first conductive circuits in the first conductive layer are connecting the first pads and the second pads, respectively.

2. A package substrate according to claim 1, wherein the first conductive circuits in the first conductive layer are connecting the first pads and the second pads, respectively, such that the first conductive circuits form a wiring layer configured to transmit data between the first electronic component and the second electronic component.

3. A package substrate according to claim 1, further comprising:
an inner interlayer resin insulation layer;
a second conductive layer formed on the inner interlayer resin insulation layer; and
a skip-via conductor penetrating through the outermost interlayer resin insulation layer and the inner interlayer resin insulation layer such that the skip-via conductor is connecting the outermost conductive layer and the second conductive layer,
wherein the first conductive layer is formed on the inner interlayer resin insulation layer, the second conductive layer is formed on the inner interlayer resin insulation layer on an opposite side with respect to the first conductive layer.

4. A package substrate according to claim 3, wherein the inner interlayer resin insulation layer does not have a via conductor formed in the inner interlayer resin insulation layer.

5. A package substrate according to claim 3, wherein the outermost interlayer resin insulation layer has a thickness which is at least twice a thickness of the inner interlayer resin insulation layer.

6. A package substrate according to claim 3, wherein the outermost conductive layer, the plurality of first conductive circuits and the second conductive layer form a strip line structure.

7. A package substrate according to claim 3, wherein the first electronic component is a logic IC device, and the second electronic component is a memory device.

8. A package substrate according to claim 1, wherein the first conductive layer does not have conductive circuits other than the plurality of first conductive circuits.

9. A package substrate according to claim 1, wherein the first conductive layer does not have conductive circuits other than the plurality of first conductive circuits, and the first conductive circuits in the first conductive layer are connecting the first pads and the second pads, respectively, such that the first conductive circuits form a wiring layer configured to transmit data between the first electronic component and the second electronic component.

10. A package substrate according to claim 1, wherein the first electronic component is a logic IC device, and the second electronic component is a memory device.

11. A package substrate according to claim 1, further comprising:
an inner interlayer resin insulation layer; and
a skip-via conductor penetrating through the outermost interlayer resin insulation layer and the inner interlayer resin insulation layer such that the skip-via conductor is connected to the outermost conductive layer,
wherein the first conductive layer is formed on the inner interlayer resin insulation layer.

12. A package substrate according to claim 11, wherein the inner interlayer resin insulation layer does not have a via conductor formed in the inner interlayer resin insulation layer.

13. A package substrate according to claim 11, wherein the outermost interlayer resin insulation layer has a thickness which is at least twice a thickness of the inner interlayer resin insulation layer.

14. A package substrate according to claim 2, wherein the first electronic component is a logic IC device, and the second electronic component is a memory device.

15. A package substrate according to claim 3, wherein the outermost interlayer resin insulation layer has a thickness which is at least twice a thickness of the inner interlayer resin insulation layer, the outermost conductive layer, the plurality of first conductive circuits and the second conductive layer form a strip line structure, and the first electronic component is a logic IC device, and the second electronic component is a memory device.

16. A method for manufacturing a package substrate, comprising:
forming an outermost interlayer resin insulation layer on a first conductive layer including a plurality of first conductive circuits;
forming on the outermost interlayer resin insulation layer an outermost conductive layer including a plurality of first pads positioned to mount a first electronic component and a plurality of second pads positioned to mount a second electronic component;
forming a plurality of first via conductors penetrating through the outermost interlayer resin insulation layer such that the first via conductors connect the first conductive layer and the first pads; and
forming a plurality of second via conductors penetrating through the outermost interlayer resin insulation layer such that the second via conductors connect the first conductive layer and the second pads,
wherein the first conductive circuits in the first conductive layer are connecting the first pads and the second pads, respectively.

17. A method for manufacturing a package substrate according to claim 16, further comprising:
forming an inner interlayer resin insulation layer on a second conductive layer; and
forming a skip via conductor penetrating through the outermost interlayer resin insulation layer and the inner interlayer resin insulation layer such that the skip via conductor connects the outermost conductive layer and the second conductive layer,
wherein the first conductive layer is formed on the inner interlayer resin insulation layer, the second conductive layer is formed on the inner interlayer resin insulation layer on an opposite side with respect to the first conductive layer.

18. A method for manufacturing a package substrate according to claim 17, wherein the forming of the inner interlayer resin insulation layer includes preparing a resin film having an seed layer, curing the resin film such that the inner interlayer resin insulation layer is formed, and the first conductive circuits in the first conductive layer are connecting the first pads and the second pads, respectively, such that the first conductive circuits form a wiring layer configured to transmit data between the first electronic component and the second electronic component

19. A method for manufacturing a package substrate according to claim 18, wherein the wiring layer comprising the seed layer is formed on the inner interlayer resin insulation layer by a semi-additive method using.

20. A method for manufacturing a package substrate according to claim 19, further comprising:
forming a skip-via conductor penetrating through the outermost interlayer resin insulation layer and the inner interlayer resin insulation layer such that the skip-via conductor connects the outermost conductive layer and the second conductive layer,
wherein the wiring layer forms a signal line for data transmission between the first electronic component and the second electronic component.
